(19) United States
(12) Patent Application Publication
(10) Pub. No.: US 2024/0327199 A1
(43) Pub. Date: Oct. 3, 2024

(54) MICROELECTROMECHANICAL DEVICE WITH MOVABLE MASS AND STOPPER MECHANISM

(71) Applicant: STMicroelectronics International N.V., Geneva (CH)

(72) Inventors: Paola CARULLI, Milano (IT); Patrick FEDELI, Senago (IT); Luca Giuseppe FALORNI, Limbiate (IT); Federico MORELLI, Milan (IT)

(73) Assignee: STMicroelectronics International N.V., Geneva (CH)

(21) Appl. No.: 18/614,435

(22) Filed: Mar. 22, 2024

(30) Foreign Application Priority Data
Mar. 27, 2023 (IT) 102023000005814

(51) Int. Cl. H02K 33/00; B81B 3/00

(52) U.S. Cl. CPC B81B 3/0051; B81B 2201/0235; B81B 2201/0242

(57) ABSTRACT

Microelectromechanical device comprising a supporting body, containing semiconductor material and a movable mass, constrained to the supporting body with a relative degree of freedom with respect to at least one motion direction, within a range of admissible positions. The device also comprises stopper elements, operable by the movable mass due to movements along the at least one motion direction and configured to apply stop forces to opposite sides of the movable mass, transversely to the at least one motion direction, when the movable mass reaches a respective endpoint of the range of admissible positions, so as to prevent the movable mass from exceeding the respective endpoint.

### BACKGROUND

### Technical Field

The present disclosure relates to a micro-electro-mechanical (MEMS) device comprising a movable mass and a stopper mechanism.

### Description of the Related Art

Inertial micro-electro-mechanical (MEMS) devices, in particular for example gyroscopes and accelerometers, base their operation on masses coupled to a supporting body, such as for example a frame or a substrate of semiconductor material, through flexures (springs) which allow the masses to oscillate along one or more directions, in order to detect the variations of a physical quantity or to function as actuators.

In response to shocks that may occur during the life of the sensors (with acceleration values up to 10³-10⁵ g), the movable masses may exceed the range of work positions considered safe. To avoid damage, for example to the springs, stopper elements are provided which are capable of limiting the allowed displacement of the movable masses.

Typical stopper elements may comprise static blocks anchored to the substrate and arranged at a given distance from the masses (in the rest position), in the motion direction, so as to allow normal operation of the device and, at the same time, define a maximum displacement allowed to movable masses (i.e., a full stroke).

The full stroke is in fact determined by a frontal impact between the movable mass and the stopper element; the latter typically has a suitably patterned surface so as to limit the stress generated at the interface between the two impacting surfaces.

The disadvantages of the known solution mainly reside in that the stop forces applied by the stopper elements may cause adhesion of the movable mass and/or damage to the structure. Furthermore, the movement direction of the movable mass after the impact against the stopper elements (rebound direction) may not be predictable since the direction of the shock forces, typically, is not perfectly collinear with the motion direction.

### BRIEF SUMMARY

The present disclosure is directed to one or more embodiments to overcome or at least mitigate the disadvantages and limitations of the state of the art.

According to the present disclosure, there is presented a MEMS device. For example, in at least one embodiment, a MEMS device may be summarized as including a supporting body containing semiconductor material; a movable mass constrained to the supporting body with a relative degree of freedom with respect to at least one motion direction within a range of positions; stopper elements operable by the movable mass due to movements along the at least one motion direction of the movable mass, and the stopper elements are configured to, in operation, apply stop forces to opposite sides of the movable mass transversely to the at least one motion direction when the movable mass reaches a respective endpoint of the range of positions to prevent the movable mass from exceeding the respective endpoint.

### BRIEF DESCRIPTION OF THE SEVERAL VIEWS OF THE DRAWINGS

For a better understanding of the present disclosure, preferred embodiments are presented, by way of non-limiting example, with reference to the attached drawings, wherein:

FIG. 1 illustrates, in top-plan view, a MEMS device according to an embodiment of the present disclosure, in a first operating configuration;

FIG. 2 illustrates, in top-plan view, a range of admissible positions of a component of the MEMS device of FIG. 1;

FIG. 3 illustrates, in top-plan view, the MEMS device of FIG. 1 in a second operating configuration;

FIG. 4 illustrates, in top-plan view, an enlarged detail of the MEMS device of FIG. 1;

FIG. 5 illustrates, in top-plan view, a MEMS device according to another embodiment of the present disclosure;

FIG. 6 illustrates, in top-plan view, a MEMS device according to a further embodiment of the present disclosure; and

FIG. 7 illustrates, in top-plan view, a range of admissible positions of a component of the MEMS device of FIG. 6.

### DESCRIPTION OF EMBODIMENTS

The following description refers to the arrangement shown in the drawings; accordingly, expressions such as “above”, “below”, “upper”, “lower”, “top”, “bottom”, “right”, “left” and the like relate to the accompanying figures and are not to be interpreted in a limiting manner.

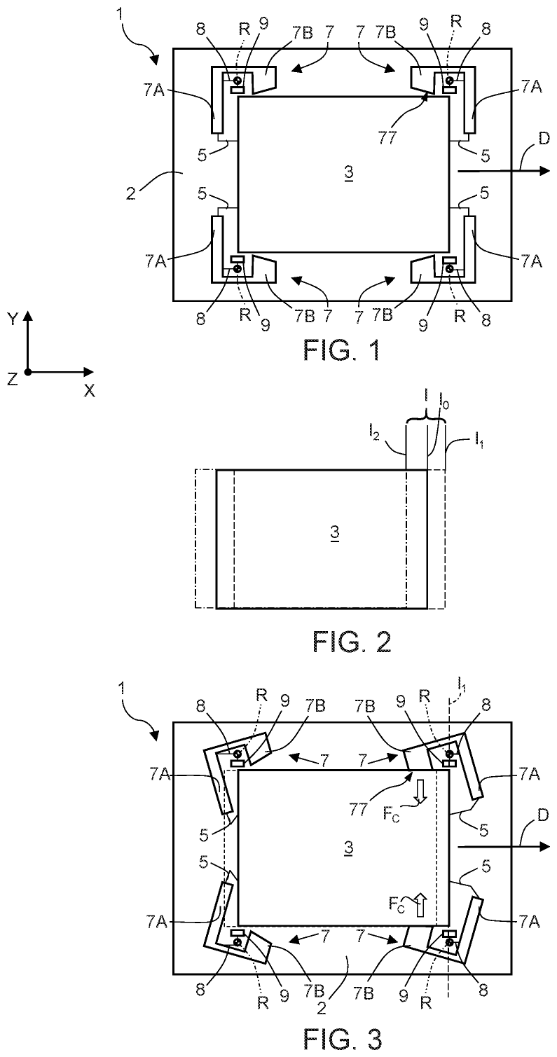

FIGS. 1-3 illustrate a microelectromechanical or MEMS device 1 according to an embodiment of the present disclosure, for example, an inertial sensor, such as an accelerometer or a gyroscope. The MEMS device 1 comprises a supporting body 2, for example a substrate of semiconductor material, and a movable mass 3 coupled to the supporting body 2 so as to be able to oscillate along one or more motion directions within a range I of admissible positions (FIG. 2), as described in more detail hereinbelow. Each range I is delimited by opposite endpoints I₁, I₂, corresponding to full-stroke positions of the movable mass 3, and includes a rest position I₀, which is not necessarily central.

In FIG. 1, the MEMS device 1 is for example shown in its rest condition (I₀ in FIG. 2), i.e. when the movable mass 3 is stationary, in the absence of external forces applied. In one embodiment, the movement of the movable mass 3 is allowed along a motion direction D, for example a detection or drive direction parallel to a horizontal axis X of a triaxial reference system of axes X, Y, Z orthogonal to each other. While the direction D is shown being directed to the right-hand side of FIG. 1, alternatively, the motion direction D when exposed to some external forces can be directed to the left-hand side of FIG. 1.

The MEMS device 1 also comprises stopper elements 7, arranged around the movable mass 3 and coupled to the supporting body 2 through anchors 9. In particular, the stopper elements 7 are supported by respective anchors 9 by means of connection elements 8 configured to allow the rotation of the stopper elements 7 around respective rotation axes R parallel to the vertical axis Z.

The movable mass 3 is connected, through coupling elements 5, to the stopper elements 7.

The coupling elements 5 comprise flexures (springs) which constrain the movable mass 3 to the stopper elements 7 and, together with the anchors 9 and the connection elements 8, keep the movable mass 3 suspended, in the direction of the vertical axis Z, with respect to the supporting body 2.

The stopper elements 7 are configured to limit the movement of the movable mass 3 along the motion direction D within the range I of admissible positions. In the MEMS device 1, the stopper elements 7 have a generic “L”-shape and are provided with transmission arms 7A and stopper arms 7B.

The stopper elements 7 are operated by the movable mass 3 through the coupling elements 5 which, in the MEMS device 1, connect the movable mass 3 to the ends of the transmission arms 7A of the stopper elements 7 opposite to the anchors 9.

During the movement of the movable mass 3 along the motion direction D allowed, the movable mass 3 operates the stopper elements 7 through the coupling elements 5.

In particular, the movable mass 3 pushes/pulls the transmission arms 7A thus causing the rotation of the stopper elements 7 around the respective rotation axes R. As shown in FIG. 3, the rotation axes R are each located between a corresponding stopper element 7 and a corresponding anchor 9.

The stopper elements 7, and in particular the stopper arms 7B, are sized so as to ensure suitable stiffness and allow normal operation of the MEMS device 1, as long as the movement of the movable mass 3 is contained within the range I of admissible positions from the rest position I₀ designed.

FIG. 3 instead shows a full-stroke condition of the movement of the movable mass 3, in particular for a movement to the right in the motion direction D, for example in response to a shock.

When the movable mass 3 reaches one of the endpoints I₁, I₂ of the range I of admissible positions (the endpoint I₁ in FIG. 3), the stopper elements 7 on the side of the movable mass 3 moving towards rotate to the point that the respective stopper arms 7B come into contact with the movable mass 3 and clamp the movable mass 3.

More precisely, ends 77 of the stopper arms 7B, due to the rotation, apply stop forces F_{C} to opposite sides of the movable mass 3 transversely to the motion direction D, thereby creating a “clamping effect.”

In the example of FIG. 3, the stop forces F_{C} are perpendicular to the motion direction D and to the axis Z. In some alternative embodiments, the clamping forces may be at some other angle transverse to the motion direction D.

For clarity of understanding, FIG. 3 also shows the position of the movable mass 3 at rest once the movable mass has reached the endpoint I₁.

The stopper elements 7 on the side of the movable mass 3 moving away are dragged by the movement of the movable mass 3 and rotate so that the respective stopper arms 7B tend to open, without interfering in the stop action.

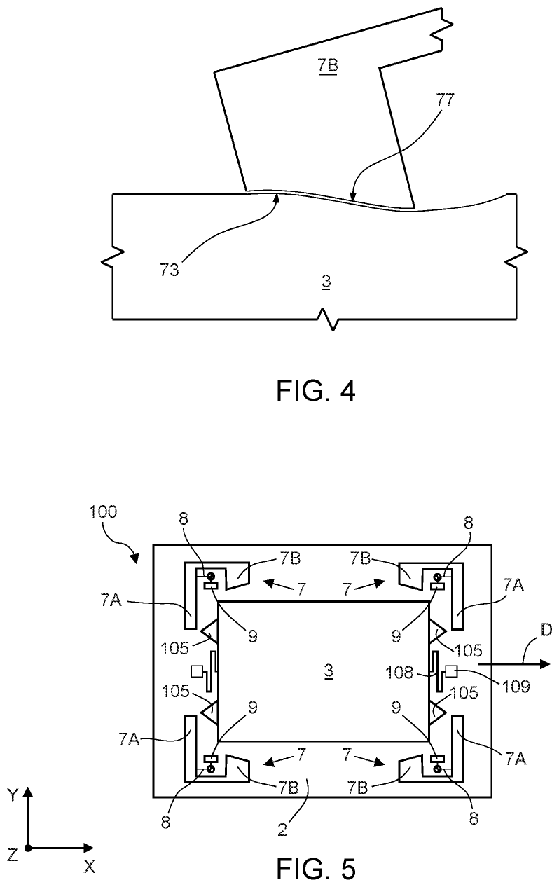

With reference to FIG. 4, the ends 77 of the stopper arms 7B are patterned so as to engage respective seats 73 on sides of the movable mass 3 when the corresponding endpoint I₁, I₂ of the range I is reached, thereby allowing control of the direction of stop forces F_{C} applied.

In FIG. 3, for example, the ends 77 of the stopper arms 7B are shaped so as to come into contact in a parallel manner to the side of the movable mass 3.

When the action of the stopper elements 7 following a shock undergone by the movable mass 3 expires, the system made by the movable mass 3, the coupling elements 5 and the stopper elements 7 returns to normal operation.

The intensity of the stop forces F_{C} may be selected according to the design preferences by acting on the ratio between the lengths of the stopper arms 7B and the transmission arms 7A.

The Applicant has verified that the stop forces F_{C} applied by the stopper arms 7B may be lower than those obtained by employing static-block stopper elements which frontally stop the movable mass 3. The stop forces F_{C} are also a balanced force system on the structure of the MEMS device 1.

The “clamping effect” that is created also limits the movement of the movable mass 3 also in the direction perpendicular to the direction preset for the movement (in FIG. 1, 3 according to the axis Y), ensuring greater stiffness to the transverse movement.

The overall benefits obtained include a lower risk of damage of the entire structure and a more controlled and predictable rebound direction of the movable mass 3.

FIG. 5 shows a MEMS device 100 according to a different embodiment of the disclosure. Elements of FIG. 5 which correspond to elements of FIG. 1 are illustrated with the same reference numerals, in particular, the supporting body 2, the movable mass 3, the stopper elements 7 and the anchors 9.

Coupling elements 105 may comprise protrusions of a rigid material, which extend from the movable mass 3 towards respective stopper elements 7. The coupling elements 105 come into contact with the transmission arms 7A of the respective stopper elements 7 on the side moving towards due to the oscillations of the movable mass 3 and cause the rotation of the respective stopper elements 7. On the side moving away, the coupling elements 105 may separate from respective stopper elements 7. In this case, the connection elements 8 exert elastic return forces which take the stopper elements 7 towards rest configurations, wherein the stopper arms 7B are separated from the movable mass 3 and do not interfere with the oscillation.

The stopper elements 7 therefore act as previously described, clamping the movable mass 3 simultaneously on opposite sides.

In the embodiment of FIG. 5, the movable mass 3 is kept suspended with respect to the supporting body 2 by means of further connection elements 108 and anchors 109. In particular, the connection elements 108 are shaped so as to allow the movement of the movable mass 3 according to the motion direction D.

In FIG. 5 the movable mass 3 is in rest condition.

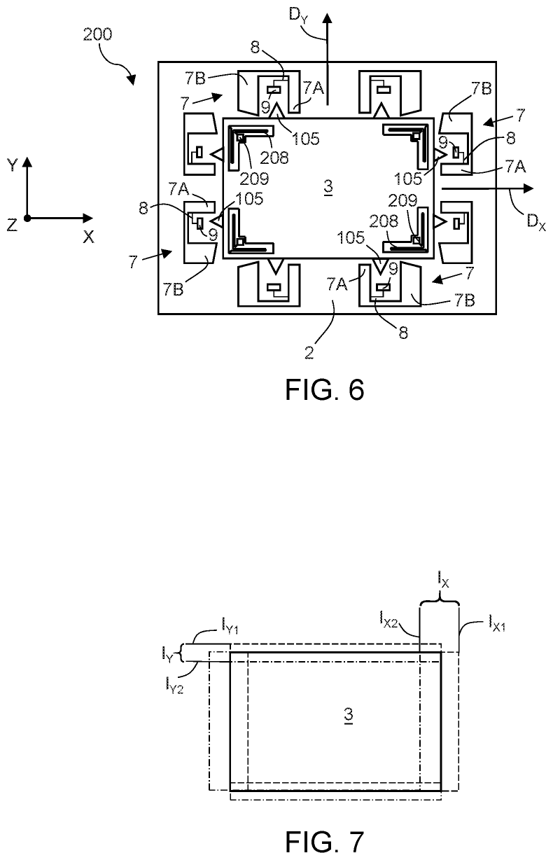

FIG. 6 shows a MEMS device 200 according to another embodiment of the disclosure. Elements of FIG. 6 which correspond to elements of FIGS. 1, 5 are illustrated with the same reference numerals.

In the MEMS device 200, the movable mass 3 is movable with a first degree of freedom along a first motion direction D_{X}, within a first range I_{X} of admissible positions, defined by a respective first endpoint I_{X1} and a respective second endpoint I_{X2}; and with a second degree of freedom along a second motion direction D_{Y}, perpendicular to the first motion direction D_{X} and to the axis Z, within a second range I_{Y} of admissible positions, defined by a respective first endpoint I_{Y1} and a respective second endpoint I_{Y2}. The endpoints I_{X1}, I_{X2} and the endpoints I_{Y1}, I_{Y2} may be different (FIG. 7).

The MEMS device 200 comprises stopper elements 7 oriented in such a way as to implement, in an independent manner, the “clamping effect” previously described for movements of the movable mass 3 which exceed both the range I_{X} of admissible positions along the first motion direction D_{X}, and the range I_{Y} of admissible positions along the second motion direction D_{Y}.

In this embodiment, the coupling elements 105 comprise protrusions of a rigid material, for example having the shape of a triangular-based prism, which extend from the movable mass 3 towards respective stopper elements 7. The stopper elements 7 are sized in such a way as not to interfere during normal operation of the MEMS device 200 and in such a way that the stop actions exerted along the motion directions D_{X}, D_{Y}, perpendicular to each other, do not interfere with one another.

The coupling elements 105 come into contact with the transmission arms 7A of the respective stopper elements 7 close to the coupling elements 105 (considered, by analogy to what has been previously described, moving towards), operating the rotation of the respective stopper elements 7 around the respective rotation axes R. The coupling elements 105 moving away may instead separate from the respective and close stopper elements 7.

For movements of the movable mass 3 which exceed the ranges I_{X}, I_{Y} of admissible positions, the stopper elements 7 therefore act as previously described, clamping the movable mass 3 simultaneously on opposite sides.

In FIG. 6, each stopper element 7 has the transmission arm 7A and the stopper arm 7B facing a same side of the movable mass 3. The stopper elements 7 which clamp the movable mass 3 for movements that exceed the range I_{X} of admissible positions along the motion direction D_{X} face first sides of the movable mass 3; the stopper elements 7 which clamp the movable mass 3 for movements that exceed the range I_{Y} of admissible positions along the motion direction D_{Y} face second sides of the movable mass 3 orthogonal to the first sides.

In the embodiment of FIG. 6, the movable mass 3 is kept suspended with respect to the supporting body 2 by means of further connection elements 208 and anchors 209. In particular, the connection elements 208 are shaped so as to allow the movement of the movable mass 3 according to the motion directions D_{X}, D_{Y}.

In FIG. 6 the movable mass 3 is in rest condition.

Finally, it is clear that modifications and variations may be made to what has been described and illustrated herein without thereby departing from the scope of the present disclosure, as defined in the attached claims.

A microelectromechanical device (1; 100; 200) may be summarized as including a supporting body (2), containing semiconductor material; a movable mass (3), constrained to the supporting body with a relative degree of freedom with respect to at least one motion direction (D; D_{X}; D_{Y}), within a range (I; I_{X}; I_{Y}) of admissible positions; stopper elements (7), operable by the movable mass (3) due to movements along the at least one motion direction and configured to apply stop forces (F_{C}) to opposite sides of the movable mass (3) transversely to the at least one motion direction when the movable mass (3) reaches a respective endpoint (I₁, I₂; I_{X1}, I_{X2}; I_{Y1}, I_{Y2}) of the range of admissible positions, so as to prevent the movable mass (3) from exceeding the respective endpoint.

The device (1; 100; 200) may include anchors (9) fixed to the supporting body (2) and connection elements (8) connecting the stopper elements (7) to the respective anchors (9).

The connection elements (8) may be configured to allow rotations of the stopper elements (7) around respective rotation axes (R) perpendicular to the at least one direction of the movement of the movable mass (3).

The stopper elements (7) may be arranged around the movable mass (3) and may be coupled to the movable mass (3) so that the stopper elements (7) cooperating to clamp the movable mass (3) rotate in respective opposite directions in response to movements of the movable mass (3) along the at least one motion direction (D; D_{X}; D_{Y}).

The device (1; 100; 200) may include coupling elements (5; 105), constrained to the movable mass (3) and may be configured to operate the stopper elements (7) due to the movement of the movable mass (3) along the at least one motion direction.

The coupling elements (5) may be fixed to the movable mass (3) and to the stopper elements (7) and the anchors (9), the connection elements (8) and the coupling elements (5) may be configured to keep the movable mass suspended with respect to the supporting body (2).

The device (100; 200) may include further connection elements (108; 208) and further anchors (109; 209), wherein the movable mass (3) may be kept suspended with respect to the supporting body (2) by the further connection elements (108; 208) and by the further anchors (109; 209), the further connection elements (108; 208) being shaped so as to allow the movement of the movable mass according to the at least one motion direction (D; D_{X}; D_{Y}) of the movable mass (3).

The coupling elements (5) may include flexures.

The coupling elements (105) may include protrusions of a rigid material carried by the movable mass (3).

The stopper elements (7) may include respective transmission arms (7A) coupled to the movable mass (3), by means of the respective coupling elements (5; 105), so as to cause the rotation of the stopper elements (7) around the respective rotation axes (R) in response to the movement of the movable mass (3) along the at least one motion direction (D; D_{X}; D_{Y}).

The stopper elements (7) may include stopper arms (7B) having ends (77) configured to clamp the movable mass (3) when the movable mass (3) reaches the respective endpoint of the range of admissible positions.

The ends (77) of the stopper arms (7B) may be patterned so as to engage respective seats (73) on sides of the movable mass (3) when the movable mass reaches the respective endpoint of the range of admissible positions.

In each stopper element (7) the transmission arm (7A) and the stopper arm (7B) may face respective orthogonal sides of the movable mass (3).

Each stopper element (7) may have the transmission arm (7A) and the stopper arm (7B) facing a same side of the movable mass (3).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microelectromechanical device comprising:
a supporting body containing semiconductor material;
a movable mass constrained to the supporting body with a relative degree of freedom with respect to at least one motion direction within a range of positions;
stopper elements operable by the movable mass due to movements along the at least one motion direction of the movable mass, and the stopper elements are configured to, in operation, apply stop forces to opposite sides of the movable mass transversely to the at least one motion direction when the movable mass reaches a respective endpoint of the range of positions to prevent the movable mass from exceeding the respective endpoint.

2. The device according to claim 1, comprising anchors fixed to the supporting body and connection elements connecting the stopper elements to the respective anchors.

3. The device according to claim 2, wherein the connection elements are configured to, in operation, allow rotations of the stopper elements around respective rotation axes perpendicular to the at least one direction of the movement of the movable mass.

4. The device according to claim 3, wherein the stopper elements are arranged around the movable mass and are coupled to the movable mass so that the stopper elements cooperate to clamp onto the movable mass by rotating in respective opposite directions in response to movements of the movable mass along the at least one motion direction.

5. The device according to claim 2, comprising coupling elements constrained to the movable mass, and the coupling elements are configured to, in operation, operate the stopper elements due to the movement of the movable mass along the at least one motion direction.

6. The device according to claim 5, wherein the coupling elements are fixed to the movable mass and to the stopper elements, and wherein the anchors, the connection elements, and the coupling elements are configured to keep the movable mass suspended with respect to the supporting body.

7. The device according to claim 2, comprising further connection elements and further anchors, wherein the movable mass is kept suspended with respect to the supporting body by the further connection elements and by the further anchors, the further connection elements being shaped so as to allow the movement of the movable mass according to the at least one motion direction of the movable mass.

8. The device according to claim 5, wherein the coupling elements comprise flexures.

9. The device according to claim 5, wherein the coupling elements comprise protrusions of a rigid material carried by the movable mass.

10. The device according to claim 5, wherein the stopper elements comprise respective transmission arms coupled to the movable mass, by means of the respective coupling elements, and the respective transmission arms are configured to, in operation, cause the rotation of the stopper elements around the respective rotation axes in response to the movement of the movable mass along the at least one motion direction.

11. The device according to claim 5, wherein the stopper elements comprise stopper arms having ends configured to, in operation, clamp onto the movable mass when the movable mass reaches the respective endpoint of the range of positions.

12. The device according to claim 11, wherein the ends of the stopper arms are patterned so as to engage respective seats on sides of the movable mass when the movable mass reaches the respective endpoint of the range of positions.

13. The device according to claim 11, wherein each respective stopper element of the stopper elements includes a transmission arm that faces a first side of the movable mass and a stopper arm that faces a second side of the movable mass transverse to the first side of the movable mass.

14. The device according to claim 11, wherein each respective stopper element of the stopper includes a transmission arm that faces a side of the movable mass and a stopper arm facing the side of the movable mass.

15. A device, comprising:
a supporting body;
a movable mass suspended from the supporting body, the movable mass including:
a rest position;
a first endpoint position directed away from the rest position in a first motion direction; and
a second endpoint position directed away from the rest position in a second motion direction different from the first motion direction;
a first pair of stopper elements that are configured to, in operation, clamp onto a pair of opposite sides of the movable mass when the movable mass is at the first endpoint, each respective stopper element of the first pair of stopper elements including:
a stopper arm including an end that abuts a corresponding side of the pair of opposite sides when the movable mass is in the first endpoint position; and
a transmission arm coupled to the stopper arm, the transmission arm is configured to, in operation, rotate the stopper arm in response to the movable mass moving towards the first endpoint position in the first motion direction;
a second pair of stopper elements that are configured to, in operation, clamp onto the pair of opposite sides of the movable mass when the movable mass is at the second endpoint, each respective stopper element of the second pair of stopper elements including:
a stopper arm including an end that abuts a corresponding side of the pair of opposite sides when the movable mass is in the second endpoint position; and
a transmission arm coupled to the stopper arm, the transmission arm is configured to, in operation, rotate the stopper arm in response to the movable mass moving towards the second endpoint position in the second motion direction.

16. The device of claim 15, wherein the first motion direction is opposite to the second motion direction.

17. The device of claim 15, wherein:
the movable mass includes a plurality of seats along the pair of opposite sides of the movable mass; and
the stopper arms of the first pair of stopper elements include ends that are patterned to engage with corresponding seats of the plurality of seats.

18. A device, comprising:
a supporting body;
a movable mass suspended from the supporting body, the movable mass having a plurality of sides, and the movable mass including:
a rest position;
a first endpoint position directed away from the rest position in a first motion direction; and
a second endpoint position directed away from the rest position in a second motion direction different from the first motion direction;
a plurality of stopper elements configured to, in operation, prevent movement of the movable mass past the first endpoint position and the second endpoint position, each respective stopper element of the plurality of stopper elements including:
a first group of stopper elements including respective stopper arms with ends that abut one or more corresponding sides of the plurality of sides of the movable mass when the movable mass is in the first endpoint position; and
a second group of stopper elements including respective stopper arms with ends that abuts one or more corresponding sides of the plurality of sides of the movable mass when the movable mass is in the second endpoint position.

19. The device of claim 18, comprising:
a plurality of anchors coupled to the supporting body; and
a plurality of connection elements coupled tot eh plurality of anchors and the movable mass, and
wherein the anchors and the plurality of connection elements provide one or more degrees of freedom for the movable mass to move between the first endpoint position and the second endpoint position.

20. The device of claim 18, wherein:
the movable mass includes a plurality of seats along the plurality of sides of the movable mass; and
the respective stopper arms of the first group of stopper elements and the second group of stopper elements each include an end that is patterned to engage with a corresponding seat of the plurality of seats.
